(19) United States
(12) Patent Application Publication
(10) Pub. No.: US 2009/0147970 A1
(43) Pub. Date: Jun. 11, 2009

(54) MOBILE TERMINAL AND SOUND INPUT/OUTPUT CONTROL METHOD FOR MOBILE TERMINAL

(75) Inventors: Hiroshi SHIMASAKI, Tokyo (JP); Satoshi MIZOGUCHI, Tokyo (JP); Naoto ITO, Tokyo (JP); Takahiro SOGOU, Yokohama-shi (JP); Taizo TOMIOKA, Yokohama-shi (JP); Satoru HARA, Yokohama-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: KABUSHIKI KAISHA TOSHIBA, Tokyo (JP)

(21) Appl. No.: 12/327,083

(22) Filed: Dec. 3, 2008

(30) Foreign Application Priority Data
Dec. 5, 2007 (JP) P2007-314947

(51) Int. Cl. H03G 3/20; H04M 1/02

(52) U.S. Cl. 381/107; 455/575.1

(57) ABSTRACT

According to one aspect of the invention, a mobile terminal includes: a case having two flat faces opposite to each other and side faces having a first side face and a second side face opposed to each other; a first sound input/output unit provided on the first side faces; and a second sound input/output unit provided on the second side face.

### CROSS-REFERENCE TO RELATED APPLICATIONS

This application is based upon and claims the benefit of priority from Japanese Patent Application No. 2007-314947, filed Dec. 5, 2007, the entire contents of which are incorporated herein by reference.

### BACKGROUND

1. Field

One embodiment of the invention relates to a position of a sound input/output unit of a mobile terminal and a sound input/output control method capable of improving the freedom of direction and reception of the mobile terminal approaching the ear and the mouth at the time of communication.

2. Description of the Related Art

A general mobile terminal has a calling function. For example, a mobile phone has a microphone and a speaker built in. The microphone collects user's voice during communication. The speaker outputs a ring for a phone call or mail, or outputs the voice of the communicating party.

As an example of a configuration of a microphone and a speaker of the known mobile phone, for example, there is an invention described in JP-A-2007-96843. FIG. 12 is a diagram illustrating a configuration of a flip type mobile phone described in JP-A-2007-96843, in which FIG. 12A is a plan view illustrating a close state of a flip portion 40 of the mobile phone, and FIG. 12B is a perspective view of the open state of the flip portion 40. A microphone 41 and a speaker 42 of the mobile phone are provided on the same face of a main body 43 at the mobile phone.

As another example of a configuration of a microphone and a speaker of the known mobile phone, there is an invention described in JP-A-H6-61913. FIG. 13 is a perspective view illustrating an open state of a folder type mobile phone. A microphone 45 and a speaker 46 are provided on faces toward substantially the same direction constituting a first case 47 and a second case 48, respectively. At the time of communicating, while the faces of the first case 47 and the second case 48 provided with the microphone 45 and the speaker 46 as reception faces approach an ear and a mouth, a user communicates using the mobile phone.

As a card type of mobile phone is capable of call function and an identification function using user's ID information.

The card type mobile phone is different from the known mobile phones described in JP-A-2007-96843 and JP-A-H6-61913. The card type mobile phone is small and thin. The size of length and width thereof are generally 85 mm×55 mm.

An example of using such a card type mobile phone is an ID card. It may be assumed that a user puts the mobile phone on a user's neck as an employee ID card. Accordingly, during receiving a call, the user makes the card type mobile phone hung on the neck approach user's ear and mouth to respond to the incoming call.

Since the microphone and the speaker of the known mobile phones described in JP-A-2007-96843 and JP-A-H6-61913 are provided substantially on the same face, the reception face approaching the ear and mouth at the time of receiving a call is fixed, and it is necessary to check the position of the microphone and the speaker of the mobile phone at the time of responding to the call.

Since the card type mobile phone is hung on the neck, it is preferable to respond to a call by making the mobile phone approach the ear and mouth without recognizing the position of the microphone and speaker at the time of responding to a call and without seeing the card type mobile phone.

Since the mobile phone is the card type, the mobile phone has evenness and has flat faces different from the known mobile phone. Accordingly, it is preferable that voice communication can be performed on any face and in any direction by approaching the ear and mouth without fixing the reception face of the card type mobile phone.

### SUMMARY OF THE INVENTION

According to an aspect of the present invention, there is provided a mobile terminal including: a case having two flat faces opposite to each other and side faces having a first side face and a second side face opposed to each other; a first sound input/output unit provided on the first side faces; and a second sound input/output unit provided on the second side face.

### BRIEF DESCRIPTION OF THE SEVERAL VIEWS OF THE DRAWINGS

A general architecture that implements the various features of the inventions will be described with reference to the drawings. The drawings and the associated descriptions are provided to illustrate embodiments of the invention and not to limit the scope of the invention.

FIG. 1A is an exemplary plan view illustrating appearance of an operation face of a card type mobile phone.

FIG. 1B is an exemplary side view illustrating appearance of the card type mobile phone.

FIG. 2 is an exemplary plan view illustrating appearance of a flat face of the card type mobile phone according to the first embodiment of the mobile phone of the invention.

FIG. 3 is an exemplary view illustrating an example of a method for carrying the card type mobile phone.

FIG. 4A is an exemplary perspective view illustrating a short side face of the card type mobile phone according to the first embodiment.

FIG. 4B is an exemplary perspective view illustrating the other side face opposite to the short side face shown in FIG. 4A.

FIG. 5 is an exemplary schematic block diagram illustrating the card type mobile phone according to the first embodiment.

FIG. 6 is an exemplary view illustrating appearance of a modified example of the card type mobile phone according to the first embodiment.

FIG. 7A is an exemplary perspective view illustrating a short side face of a card type mobile phone according to a second embodiment.

FIG. 7B is a perspective view illustrating the other side face opposite to the short side face shown in FIG. 7A.

FIG. 8 is an exemplary schematic block diagram illustrating the card type mobile phone according to the second embodiment.

FIG. 9 is an exemplary diagram time-serially illustrating a microphone/speaker switching process performed on the basis of voice recognition information obtained from a voice recognizing unit.

FIG. 10 is an exemplary diagram time-serially illustrating a microphone/speaker switching process performed on the basis of relative position information obtained from an acceleration sensor.

FIG. 11 is an exemplary plan view illustrating appearance of an operation face of a card type mobile phone according to a modified example of the second embodiment of the mobile phone of the invention.

FIG. 12A is an exemplary plan view illustrating appearance of the known flip type mobile phone.

FIG. 12B is a perspective view illustrating appearance of the known flip type mobile phone.

FIG. 13 is an exemplary perspective view illustrating appearance of the known folder type mobile phone.

### DETAILED DESCRIPTION

Embodiments of a mobile terminal and a sound input/output control method of the mobile terminal according to the invention will be described with reference to the accompanying drawings.

### First Embodiment

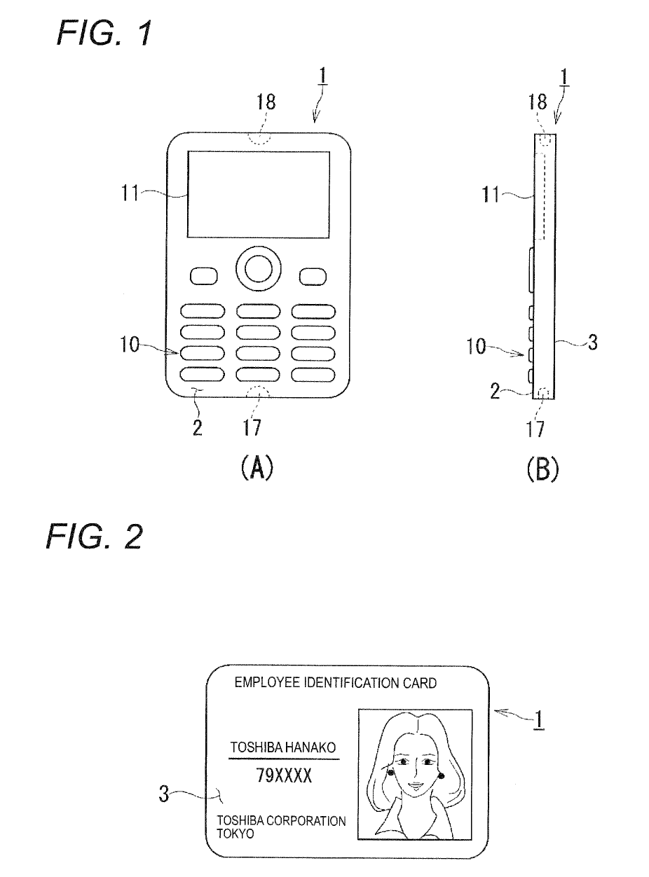

FIG. 1 is a illustrating appearance view of a card type mobile phone according to a mobile terminal of the invention, in which FIG. 1A is a plan view illustrating appearance of an operation face 2 of the card type mobile phone 1, and FIG. 1B is a side view illustrating appearance of the card type mobile phone 1. FIG. 2 is a plan view illustrating appearance of a card face 3 of the card type mobile phone 1.

The card type mobile phone 1 has a substantially rectangular operation face formed of opposite short sides and long sides, a card face, and four side faces forming a thickness of the card type mobile phone 1. An example of the size of the card type mobile phone 1, the size of length and width is 85 mm×55 mm. The thickness thereof may be, for example, about 1 mm. However, if the thickness is smaller or larger than the size, it is possible to configure the card type mobile phone 1.

The card type mobile phone 1 has at least a communication function. In addition, the card type mobile phone 1 has some identification functions such as an identification card, a basic resident register card, in which ID information is recorded, a driver's license, and a health insurance card. These identification functions are used as a non-contact IC card having a radio tag for RFID (Radio Frequency Identification), and ID information is stored in the non-contact IC card. An e-money function or the like may be provided in addition to the ID information.

Keys 10 such as number keys of “0” to “9”, a call key, a end/power key, a clear key, and a menu key are provided on the surface of the operation face 2 of the card type mobile phone 1, and various instructions can be input using the key 10.

A cross key and an OK key are provided above the keys 10, and a user can move a cursor moved up, down, left, and right by operating the cross key up, down, left, and right. Specifically, it is possible to perform various operations such as a scroll operation of a phone number list or an e-mail displayed on a display 11 provided on the operation face 2.

It is possible to decide various functions by pressing the OK key. Specifically, when a user selects a desired phone number from a plurality of phone numbers in the phone number list displayed on the display 11 by operating the cross key and then the OK key is pressed in an inward direction of the card type mobile phone 1, the selected phone number is decided and it is possible to perform a calling process for the phone number.

The display 11 provided on the operation face 2 displays a reception state of radio wave, a remaining amount of battery, a name or a phone number of a communicating party registered as a phone number, a transmission history, a content of an e-mail, a simple home page, and so on. The display 11 may be an LCD (Liquid Crystal Display), a PDP (Plasma Display Panel), an organic EL (Electro Luminescence) display, an SED (Surface-conduction Electron-emitter Display), or the like.

As shown in FIG. 2, ID card information as an employee identification card is described on the card face 3 of the card type mobile phone 1. The ID card information includes a name, an employee number, a face photograph, a company name, and an address of a user of the card type mobile phone 1. For example, the card type mobile phone 1 is carried in a manner of hanging on a neck using a neck strap 4. The neck strap 4 may be directly suspended to the card type mobile phone 1 and may be suspended to a case (not shown) for housing the card type mobile phone 1.

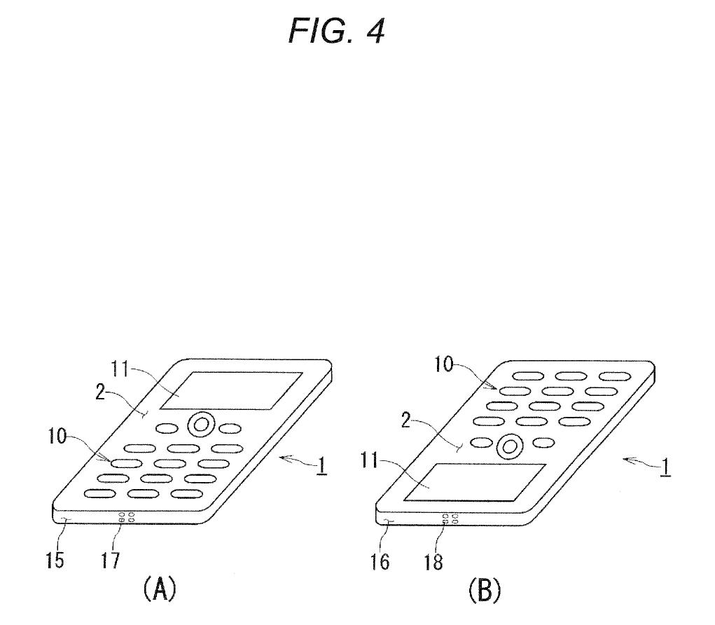

FIG. 4 is a perspective view illustrating appearance of the card type mobile phone 1 in a state where the operation face 2 thereof is upward, in which FIG. 4A is a perspective view illustrating one short side face 15 of the card type mobile phone 1 and FIG. 4B is a perspective view illustrating the other short side face 16 opposite to the short side face 15 shown in FIG. 4A.

A microphone 17 and a speaker 18 as sound input/output units may be provided substantially at the centers of the opposite short side faces of the card type mobile phone 1, respectively.

The microphone 17 as a sound input unit is provided substantially at the center of the short side face 15 shown in FIG. 4A. The microphone 17 collects user's voice at the time of voice communication. The speaker 18 as the other sound output unit is provided substantially at the center of the short side face 16 shown in FIG. 4B. The speaker 18 outputs a ring for a call or a mail at the time of waiting, and outputs voice or the like of a communicating party at the time of communicating.

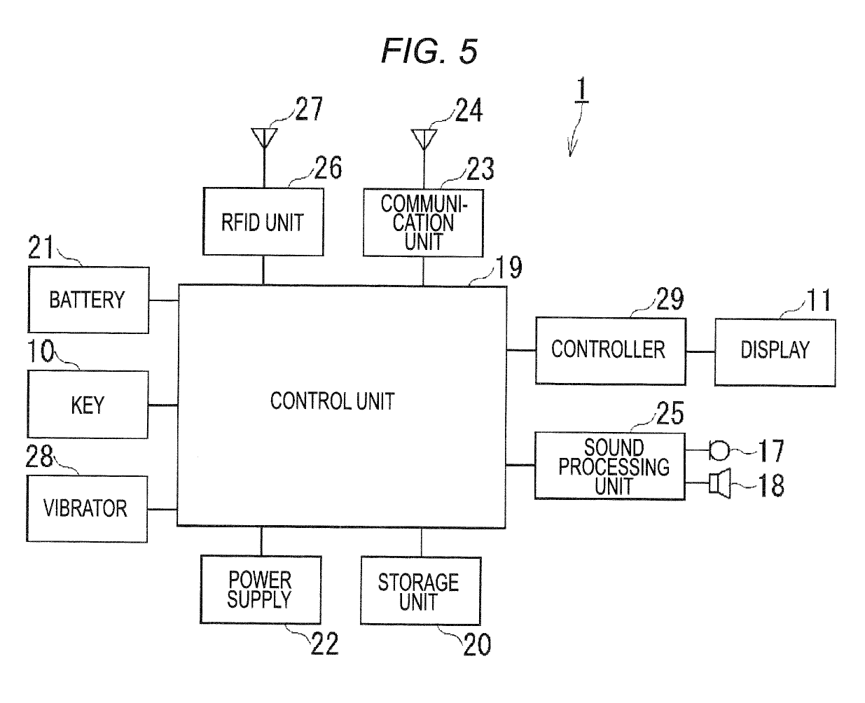

FIG. 5 is a schematic block diagram illustrating the card type mobile phone 1.

A control unit 19 of the card type mobile phone 1 is formed of a CPU (Central Processing Unit), a ROM (Read Only Memory), a RAM (Random Access Memory), and the like. The CPU performs various processes on the basis of programs stored in the ROM or various application programs loaded from a storage unit 20 onto the RAM. The CPU generates various control signals and supplies the control signals to units, thereby overall controlling the card type mobile phone 1. The RAM appropriately stores data or the like necessary for the various processes performed by the CPU.

The storage unit 20 is formed of, for example, a flash memory that is a non-volatile memory capable of electrically renewing and erasing, a HDD (Hard Disc Drive), and the like. The storage unit 20 stores various application programs performed by the CPU of the control unit 19 and various data groups.

A communication unit 23 processes various signals for radio communication using radio wave with a predetermined base station through an antenna 24. A sound processing unit 25 generates an analog sound signal from sound collected by the microphone 17, converts the analog sound signal into a digital sound signal, and transmits the digital sound signal to the communication unit 23. The communication unit 23 receives the digital sound signal through the antenna 24. The sound processing unit 25 converts the digital sound signal received through the antenna 24 into an analog sound signal, and outputs the analog sound signal as voice from the speaker 18 at the time of voice communication.

An RFID unit 26 is an IC chip or the like, and has an RFID control unit for controlling readout of individual information of a person or an object stored in the memory. The RFID unit 26 is provided with an RFID radio unit for radio communication in an UHF band through an antenna 27. The RFID unit 26 transmits data such as ID information to a separately provided RFID reader.

A controller 29 controls display of various images such as a reception state of radio wave and a remaining amount of battery displayed on the display 11.

A power supply 22 generates a predetermined operation power voltage from the output power of a battery 21 and supplies the voltage to each circuit unit. A vibrator 28 notifies a user of an incoming call by vibration.

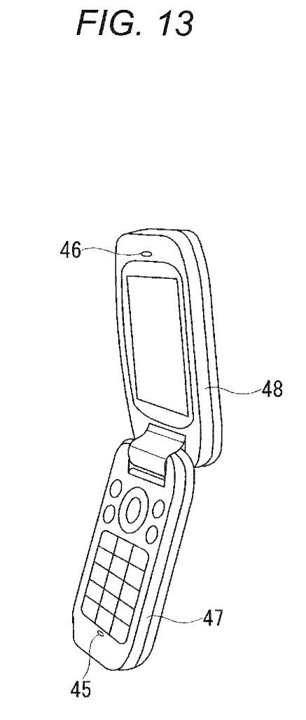

Meanwhile, in the mobile phone as the known mobile terminal, the microphone 17 and the speaker 18 are provided substantially on the same face, and thus a reception face which are provided in the face in FIG. 12 and FIG. 13.

However, the microphone 17 and the speaker 18 of the card type mobile phone 1 according to the present embodiment are provided on one pair of opposite side faces. Accordingly, even when the an ear and a mouth are approaching either the operation face 2 and the card face 3, it is possible to collect user's voice and to output voice of a communicating party. Therefore, even either the face 2 and the card face 3 approaches the ear and the mouth, the user can perform voice communication.

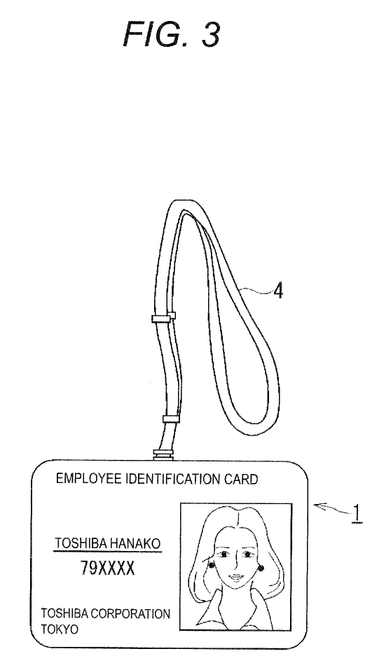

For this reason, as shown in FIG. 3 as an example, even when the card type mobile phone 1 is hung on the neck using the neck strap 4, the reception face has been approached an ear and a mouth at the time of responding to a call is not fixed and the user can respond to the call using any face of the mobile phone. Accordingly, the degree of freedom of a holding type is high, and it is unnecessary to check the reception face of the mobile phone at the time of incoming call.

When the operation face 2 of the card type mobile phone 1 faces the user, it is relatively easy to distinguish the position of the microphone 17 and the speaker 18. However, when the card face 3 faces the user and there is an incoming call, it may be difficult to distinguish what side is made to face the ear.

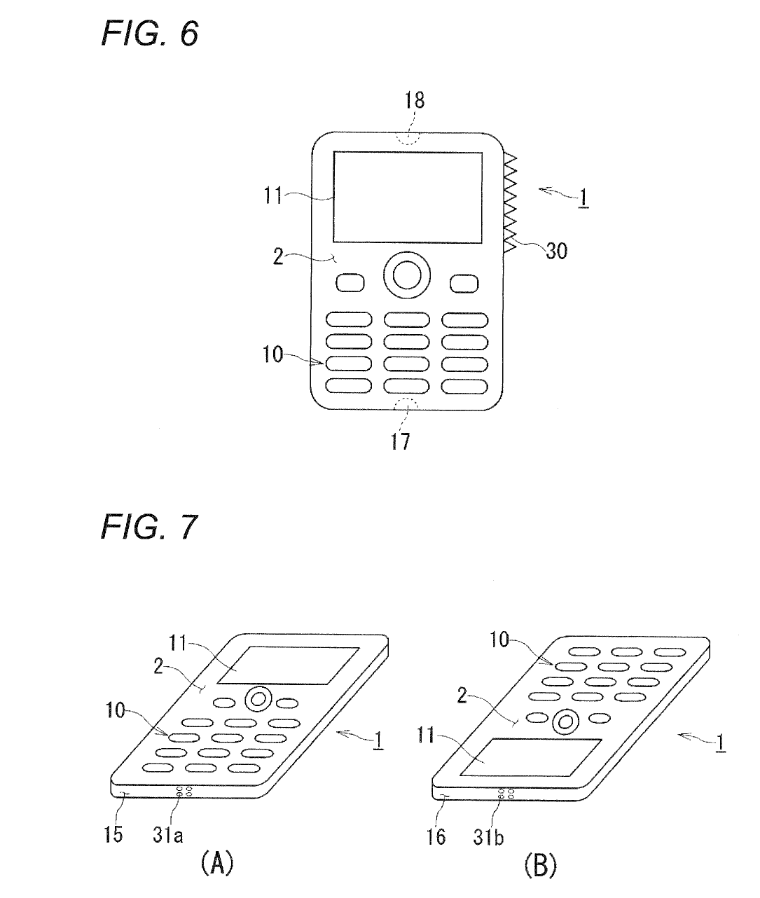

Thus, a distinguishing portion shown in FIG. 6 may be provided to easily distinguish the position of the microphone 17 and the position of the speaker 18 of the card type mobile phone 1. The distinguishing portion may be realized, for example, by an unevenness portion 30 provided on the long side face of the card type mobile phone 1 and at the upper part close to the speaker 18.

The user can distinguish the position of the microphone 17 and the position of the speaker 18 with the unevenness portion 30. Even when the card face 3 faces the user at the time of incoming call, the user can tactually or auditorily distinguish the position of the speaker 18 approaching the ear by tactile sensation obtained from the unevenness portion 30 according to the action of catching and holding the card type mobile phone 1, or by seeing the unevenness portion 30 with the naked eyes.

The unevenness portion 30 as the distinguishing portion may be, for example, a groove formed on the side face and a side button provided as the key 10. An LED (Light Emitting Diode) provided close to the microphone 17 or close to the speaker 18 may be used as the distinguishing portion.

In the embodiment, the microphone 17 and the speaker 18 are provided substantially at the centers of the short side faces 15 and 16 of the card type mobile phone 1, but the invention is not limited thereto and they may be provided at any position on the side faces of the card type phone. For example, the microphone 17 may be provided at the corner of the short side face 15, and the speaker 18 on the opposite short side face 16 and at the opposite angle of the microphone 17. A distance between the microphone 17 and the speaker 18 can be longest by providing the microphone 17 and the speaker 18 at the opposite angles, respectively. For this reason, the microphone 17 can more approach the mouth and the speaker 18 can approach the ear in consideration of human technology, in order to improve a voice communication.

The microphone 17 and the speaker 18 are provided on the short side faces 15 and 16 of the card type mobile phone 1, but they may be provided on the opposite long side faces. Alternatively, the microphone 17 may be provided on the long side face and the speaker 18 may be provided on the short side face.

The card type mobile phone may be provided with an earphone function, and voice of a communicating party may be output through the earphone. When the voice of the communicating party is output through the earphone, the micro phone 17 can be freely disposed and the degree of freedom of the holding type can be further improved, thereby appropriately responding to a call.

The case of the card type mobile phone 1 is substantially rectangular, but the invention is not limited thereto. For example, the case may be formed of a square, a polygon, a circle, and the other shapes.

### Second Embodiment

A second embodiment of a card type mobile phone according to a sound input/output control method for a mobile terminal of the invention will be described with reference to the accompanying drawings.

The card type mobile phone of the second embodiment is different from the first embodiment in that the microphone 17 and the speaker 18 provided on the short side faces 15 and 16 of the card type mobile phone shown in FIG. 4 are replaced by microphone/speakers 31a and 31b as the sound input/output units having both functions of the microphone and the speaker, respectively. The other difference is that a voice recognizing unit and a relative position recognizing unit are provided.

FIG. 7 are perspective views illustrating appearances of the card type mobile phone 1 according to the second embodiment in a state where the operation face 2 is upward, in which FIG. 7A is a perspective view illustrating a short side face 15 of the card type mobile phone 1, and FIG. 7B is a perspective view illustrating the other short side face opposite to the short side face 15 shown in FIG. 7A. The same reference numerals and signs are given to the configurations and parts corresponding to those of the first embodiment, and the repeated description is omitted.

Microphone/speakers 31a and 31b are provided substantially at the centers of the short side faces 15 and 16 of the card type mobile phone 1, respectively. The microphone/speakers 31a and 31b have both functions of the microphone and speaker, and are controlled to be switched to any function of the microphone or speaker at the time of waiting, receiving a call, or communicating.

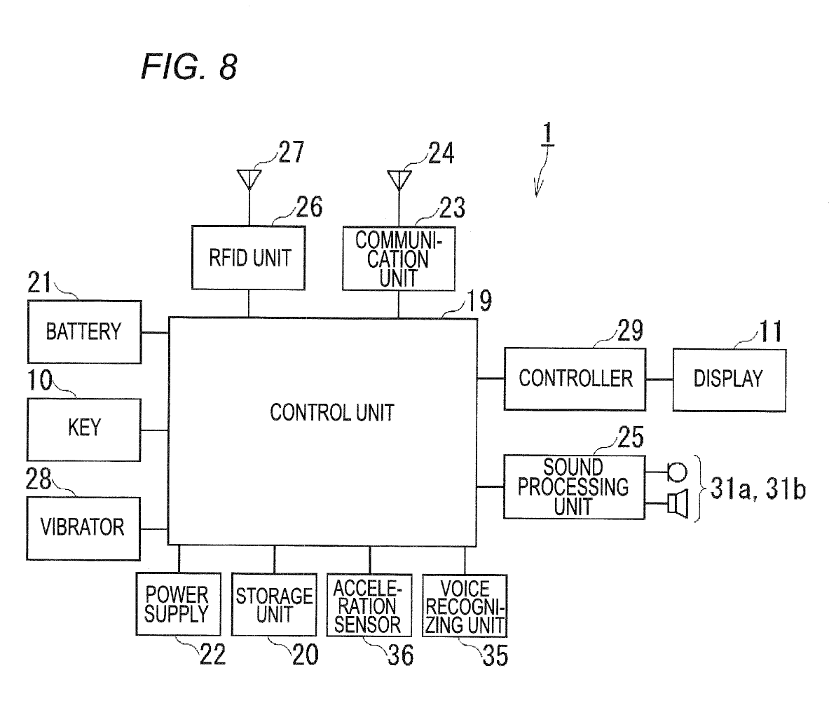

FIG. 8 is a schematic block diagram of the card type mobile phone 1. Difference from the card type mobile phone according to the first embodiment is that a voice recognizing unit 35 and an acceleration sensor 36 are provided.

At the time of communicating when the microphone/speakers 31a and 31b serve as the microphone and are in a sound input enabled state, the voice recognizing unit 35 recognizes volume of voice based on a sound signal output from a user. The control unit 19 determines that one microphone/speaker in which the volume of the voice larger than that of the other microphone/speaker is recognized by the voice recognizing unit 35 has served as the microphone collecting sound from a user's mouth, and then the microphone/speaker serves as the microphone at the later communicating. The control unit 19 determines that if the volume of the voice from the microphone is smaller than that of the other microphone/speaker, recognizing unit 35 has served as the speaker held to a user's ear, and then the microphone/speaker serves as the speaker.

The acceleration sensor 36 is a one-axis for measuring an acceleration component and is a sensor variation in acceleration in an up-down axial direction. The acceleration sensor 36 operates at the same time of performing a communication starting process by pressing a reception button. The acceleration sensor 36 recognizes the relative positions of the microphone/speakers 31a and 31b of the card type mobile phone 1 until the calling is ended. The acceleration sensor 36 is provided as a relative position recognizing unit for obtaining position information of the card typy phone.

For example, the acceleration sensor 36 is enabled at the same time of performing the call starting process. And then the sensor 36 recognizes the relative position between the microphone/speakers 31a and 31b of the card type mobile phone 1, when a user holds the card type mobile phone 1 to user's ear and mouth. The control unit 19 determines that one microphone/speaker recognized as positioned on the upside from the relative position information of the microphone/speakers 31a and 31b by the acceleration sensor 36 has served as the speaker held to a user's ear, and the microphone/speaker serves as the speaker thereafter. Meanwhile, the control unit 19 determines that the other microphone/speaker recognized as positioned on the downside has served as the microphone held to a user's mouth, and the microphone/speaker serves as the microphone thereafter.

The acceleration sensor 36 continuously operates during the call. For example, even when the microphone/speaker functioning as the microphone and the other microphone/speaker functioning as the speaker are switched to each other by turning the card type mobile phone 1, the acceleration sensor 36 recognizes the relative position again between the microphone/speakers 31a and 31b of the card type mobile phone 1. On the basis of the relative position recognized by the acceleration sensor 36, the control unit 19 controls the microphone/speakers 31a and 31b to suitably serve as the microphone and the speaker.

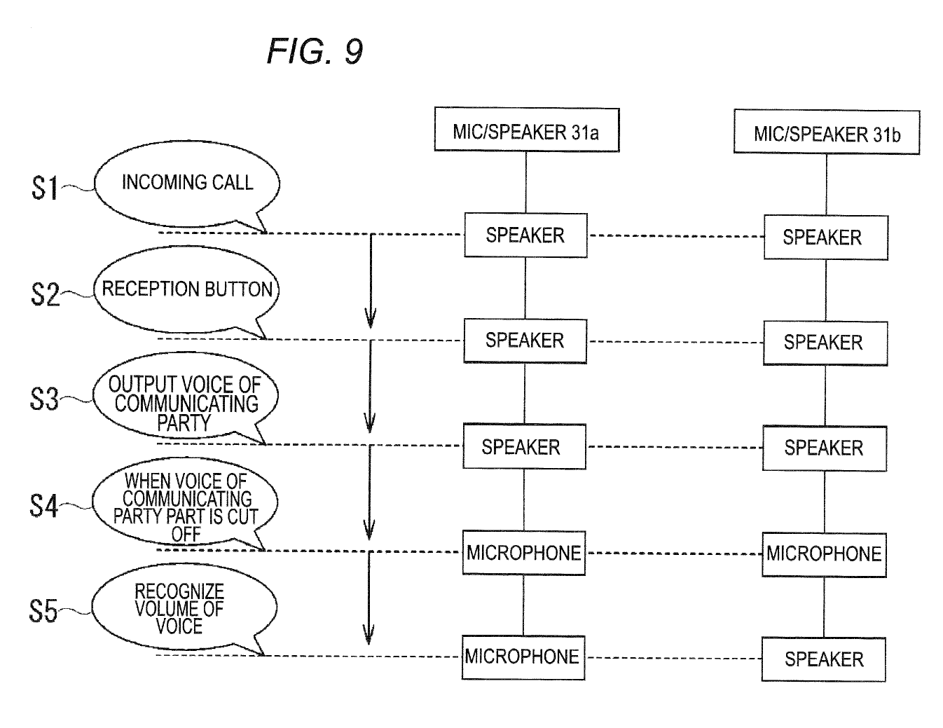

FIG. 9 is a diagram time-serially illustrating a sound input/output control method for the card type mobile phone according to the switching process of the microphone function and the speaker function of the microphone/speakers 31a and 31b on the basis of the voice recognition information obtained from the voice recognizing unit 35.

When the card type mobile phone 1 receives an incoming call, the control unit 19 controls at least one of the microphone/speakers 31a and 31b to output a ring (Step S1). When a user presses a reception button, to which a communication starting process is assigned, among the keys 10, the communication is started (Step S2). At the time of starting the communication, both of the microphone/speakers 31a and 31b serve as the speaker, as well as at the time of the incoming call.

When a communicating party starts communication, the control unit 19 outputs voice of the communicating party from both of the microphone/speakers 31a and 31b (Step S3). When the communication of the communicating party is cut, both of the microphone/speakers 31a and 31b serve as a microphone and are in a sound input enabled state for the user of the card type mobile phone 1 (Step S4).

The microphone/speakers 31a and 31b serving as the microphone collect voice output from the user of the card type mobile phone 1, and the voice recognizing unit 35 recognizes the volume of the voice based on a sound signal (Step S5). At this time, the control unit 19 controls the microphone/speaker 31a, in which the volume of the voice larger than that of the microphone/speaker 31b is recognized, to serve as the microphone, and controls the microphone/speaker 31b, in which the volume of the voice larger than that of the microphone/speaker 31a is recognized, to serve as the speaker, thereby continuing the voice communication thereafter.

In Step S4 where both of the microphone/speakers 31a and 31b serve as the microphone, the case where the communication with the communicating party is cut has been described as an example of the sound input enabled state, but the invention is not limited thereto. For example, in a case where the other state is the sound input enabled state, the volume of the voice based on the sound signal may be recognized in Step S5.

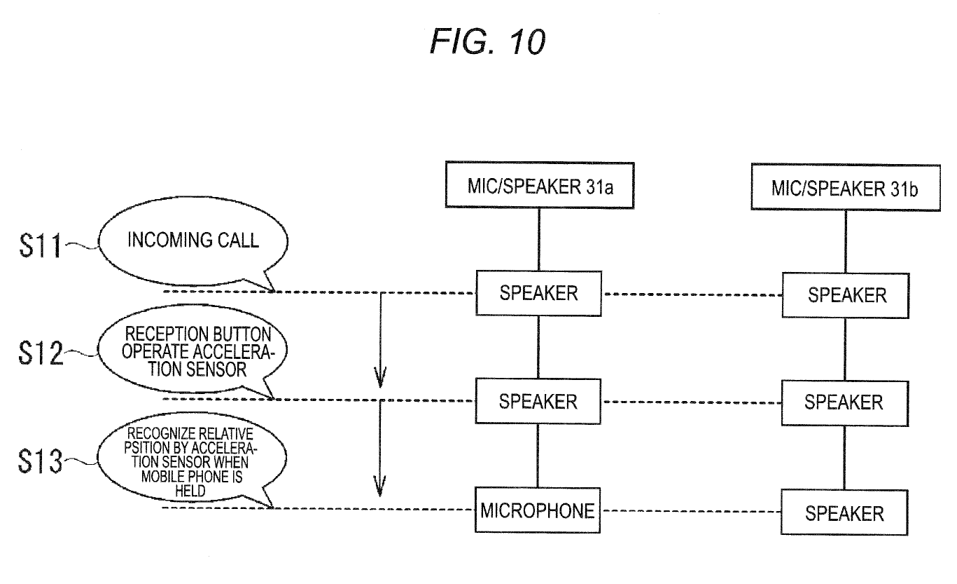

FIG. 10 is a diagram time-serially illustrating the sound input/output control method for the card type mobile phone according to the switching process of the microphone function and the speaker function of the microphone/speaker 31a and 31b, on the basis of the relative position information obtained from the acceleration sensor 36.

When the card type mobile phone 1 receives an incoming call, the control unit 19 controls at least one of the microphone/speakers 31a and 31b to output a ring (Step S11). When a user presses a reception button, to which a communication starting process is assigned, among the keys 10, the communication is started. At the same time, the acceleration sensor 36 operates (Step S12).

When a user holds the card type mobile phone 1 to user's ear and mouth at the time of responding to a call, the acceleration sensor 36 recognizes the relative position between the microphone/speakers 31a and 31b of the card type mobile phone 1 (Step S13)

The control unit 19 determines that the microphone/speaker 31a recognized as positioned on the downside has served as the microphone held to a user's mouth, and then the microphone/speaker 31a serves as the microphone thereafter. Meanwhile, the control unit 19 determined that the microphone/speaker 31b has served as the speaker held to a user's ear, and then the microphone/speaker 31b serves as the speaker. Thereafter, the voice communication continues.

The acceleration sensor 36 operates until the end of the communication. When the microphone function and the speaker function of the microphone/speakers are switched by turning the card type mobile phone 1 by the user, the control unit 19 can suitably switch the functions of the microphone/speakers 31a and 31b.

According to the card type mobile phone 1 and the sound input/output control method for the mobile terminal, there are provided the microphone/speakers 31a and 31b that can be switched to the microphone function and the speaker function on the basis of the volume of the voice based on the sound signal and the relative position information of the microphone/speakers 31a and 31b, as the sound input/output units of the card type mobile phone 1. Therefore, it is possible to communicate without considering any hold of the card type mobile phone 1 at the time of responding to a call.

According to the card type mobile phone and the sound input/output control method for the mobile terminal, even when any one of the operation face 2 and the card face 3 as the reception face approaches the ear and the mouth, it is possible to communicate, and the side faces approaching the ear and the mouth is not fixed. Accordingly, the degree of freedom of the holding type of the card type mobile phone is high, and it is effective that it is possible to communicate without considering the reception face and direction of the mobile phone at the time of responding a call.

For example, even when the card type mobile phone 1 is hung on a user's neck using the neck strap 4 as shown in FIG. 3, it is unnecessary to check the reception face and direction of the card type mobile phone 1 at the time of responding a call. Moreover, it is possible to improve convenience in addition to the small size and light weight that are characteristics of the card type mobile phone 1.

The voice recognizing unit 35 and the acceleration sensor 36 may be used together or separately. When the microphone and speaker can be distinguished according to the holding type of the card type mobile phone 1, for example, when a user lies down and the card type mobile phone 1 is used in a horizontal state, it is difficult to distinguish the microphone/speakers 31a and 31b on the basis of the relative position information. In such a case, it is effective to use the voice recognizing unit as the distinguish unit, in addition to the acceleration sensor 36.

When the switching process of the microphone/speakers 31a and 31b is performed on the basis of the volume of the voice based on the sound signal recognized by the voice recognizing unit 35 and then the positions of the microphone and the speaker are reversed by turning the card type mobile phone 1 by the user, the functions as the microphone and the speaker is not exhibited. In such a case, it is effective to perform the switching process of the microphone/speaker 31a and 31b by recognizing the relative position of the microphone/speakers 31a and 31b using the acceleration sensor 36.

The card type mobile phone 1 is provided with the microphone/speakers 31a and 31b as the sound input/output units having both functions of the microphone and the speaker, but the invention is not limited thereto. For example, the microphone 17 and the speaker 18 described in the first embodiment may be provided on the short side faces 15 and 16, respectively.

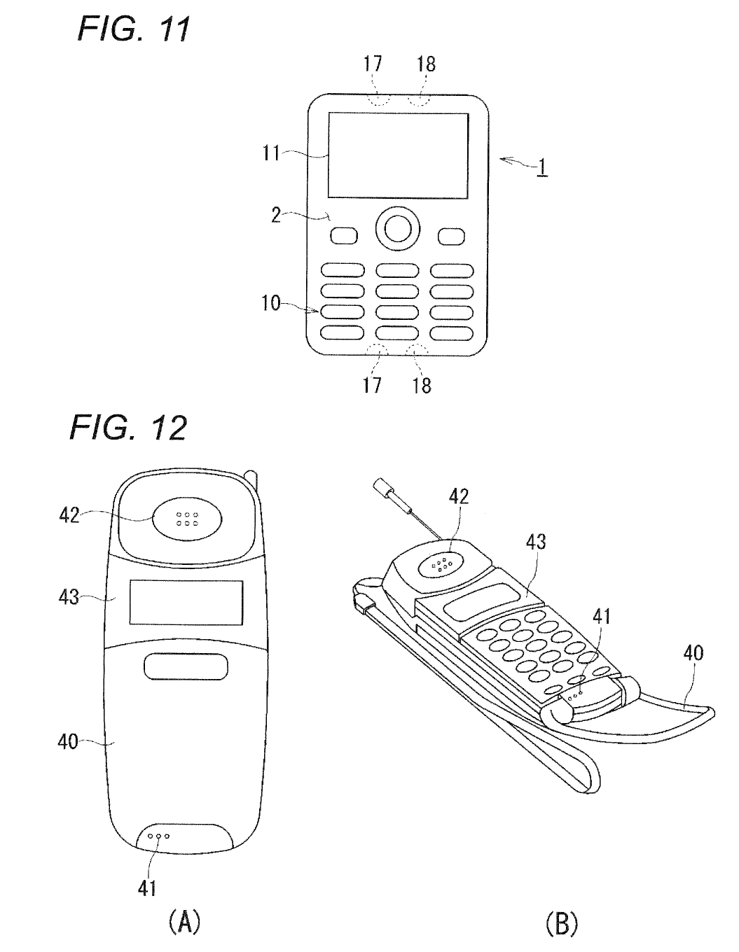

FIG. 11 is a plan view illustrating appearance of the operation face 2 of the card type mobile phone 1 provided with the microphone 17 and the speaker 18 on each of the short side faces 15 and 16. For example, when it is determined that the microphone 17 and the speaker 18 provided on one short side face have serve as the microphone using the voice recognizing unit 35 or the like, the control unit 19 performs a suitable switching process, for example, the control unit 19 stops the speaker 18 and operates the microphone 17. The switching process is the same as the switching process of the microphone function and the speaker function described with reference to FIG. 9 and FIG. 10, and thus the detailed description is omitted.

The one-axis acceleration sensor is applied as the acceleration sensor 36, but 2-axis acceleration sensor or 3-axis acceleration sensor may be applied. It is possible to sense inclination or variation in acceleration in up, down, left, and right directions of the card type mobile phone 1 by using the 2-axis or 3-axis acceleration sensor. In addition, the relative position of the microphone/speakers 31a and 31b or the like are recognized, and thus it is possible to obtain more specific relative position information.

The information obtained from the voice recognizing unit 35 and the acceleration sensor 36 is used as the information necessary for the switching process of the microphone and the speaker, but the invention is not limited thereto. For example, the other information for distinguishing the microphone/speaker used as the microphone function and the microphone/speaker used as the speaker function may be used.

The invention has been made in consideration of such circumstances, and is to provide a mobile terminal and a sound input/output control method for the mobile terminal capable of improving the degree of freedom of a holding type at the time of responding to a voice call, thereby appropriately receiving the call.

According to the mobile terminal and the sound input/output control method for the mobile terminal, it is possible to improve the degree of freedom of the holding type of the mobile terminal at the time of responding to a voice call.

What is claimed is:

1. A mobile terminal comprising:
a case having two flat faces opposite to each other and side faces having a first side face and a second side face opposed to each other;
a first sound input/output unit provided on the first side faces; and
a second sound input/output unit provided on the second side face.

2. The mobile terminal according to claim 1, wherein each of the flat faces is a rectangle having short sides and long sides,
wherein the first side face is adjacent to the flat faces with the short sides thereof, and
wherein the second side face is adjacent to the flat faces with the short sides thereof.

3. The mobile terminal according to claim 1, wherein each of the sound input/output units is dedicated to function as a sound output unit or a sound input unit.

4. The mobile terminal according to claim 3, further comprising a distinguishing portion that visually or tactually distinguishes a position of at least one of the sound output unit or the sound input unit.

5. The mobile terminal according to claim 1, further comprising:
a voice recognizing unit configured to recognize volume of voice based on sound signals input from the sound input/output units; and
a switching unit configured to select one of the sound input/output units to function as a sound input unit, which is larger in the volume of voice input than the other.

6. The mobile terminal according to claims 1, further comprising:
a position recognizing unit configured to acquire relative position information with respect to the sound input/output units; and
a switching unit configured to determine whether each of the sound input/output units functions as the sound output unit or the sound input unit based on the relative position information.

7. A sound input/output control method for a mobile terminal having a plurality of sound input/output units, the method comprising:
outputting a ringtone from at least one of sound input/output units when the mobile terminal receives a voice call;
outputting voice of a communicating party from the sound input/output units when the voice call is picked up on the mobile terminal;
sensing volume of voice input at the sound input/output units when the sound input/output units are set in a sound input enabled state; and
allowing the sound input/output units with the largest sensed volume to function as a sound input unit while allowing the other to function as a sound output unit.

8. A sound input/output control method for a mobile terminal having a plurality of sound input/output units, the method comprising:
outputting a ringtone from at least one of sound input/output units when the mobile terminal receives a voice call;
outputting voice of a communicating party from the sound input/output units when the voice call is picked up on the mobile terminal;
acquiring relative position information of the sound input/output units; and
allowing each of the sound input/output units to function as the sound output unit or the sound input unit based on the relative position information.

9. The mobile terminal according to claim 1, further comprising:
a voice recognizing unit configured to recognize volume of voice based on sound signals input from the sound input/output units; and
a switching unit configured to select one of the sound input/output units to function as a sound input unit, which is larger in the volume of voice input than the other.

10. The mobile terminal according to claims 2, further comprising:
a position recognizing unit configured to acquire relative position information with respect to the sound input/output units; and
a switching unit configured to determine whether each of the sound input/output units functions as the sound output unit or the sound input unit based on the relative position information.

11. The mobile terminal according to claims 5, further comprising:
a position recognizing unit configured to acquire relative position information with respect to the sound input/output units; and
a switching unit configured to determine whether each of the sound input/output units functions as the sound output unit or the sound input unit based on the relative position information.

12. The mobile terminal according to claims 9, further comprising:
a position recognizing unit configured to acquire relative position information with respect to the sound input/output units; and
a switching unit configured to determine whether each of the sound input/output units functions as the sound output unit or the sound input unit based on the relative position information.

13. The mobile terminal according to claim 1, wherein each of the flat faces is a rectangle having short sides and long sides,
wherein the first side face is adjacent to the flat faces with the long sides thereof, and
wherein the second side face is adjacent to the flat faces with the long sides thereof.

14. The mobile terminal according to claim 1, wherein each of the flat faces is a rectangle having short sides and long sides,
wherein the first side face is adjacent to the flat faces with the short sides thereof, and
wherein the second side face is adjacent to the flat faces with the long sides thereof.

15. The mobile terminal according to claim 4, wherein the distinguishing portion includes concave portion.

16. The mobile terminal according to claim 4, wherein the distinguishing portion includes convex portion.

17. The mobile terminal according to claim 4, wherein the distinguishing portion includes concave portion.

18. The mobile terminal according to claim 4, wherein the distinguishing portion includes a LED.

19. The mobile terminal according to claims 6, wherein the position recognizing unit includes a acceleration sensor for sensing variation in acceleration in an up-down axial direction of the mobile terminal.

20. The mobile terminal according to claims 7, wherein the acceleration sensor is 2-axis acceleration sensor.
